(19) United States
(12) Patent Application Publication
(10) Pub. No.: US 2025/0275247 A1
(43) Pub. Date: Aug. 28, 2025

(54) Stretchable Display Device and Method of Manufacturing the Same

(71) Applicant: LG Display Co., Ltd., Seoul (KR)

(72) Inventors: Jun-Hyuk Song, Paju-si (KR); Sung-Joon Min, Paju-si (KR); Yeon-Jun Oh, Paju-si (KR); Do-Joong Kim, Paju-si (KR); Tae-Hyun Kim, Paju-si (KR)

(21) Appl. No.: 18/962,034

(22) Filed: Nov. 27, 2024

(30) Foreign Application Priority Data
Feb. 27, 2024 (KR) 10-2024-0027902

(51) Int. Cl. H01L 27/12; H01L 25/16; H01L 33/62

(52) U.S. Cl. CPC H10D 86/60; H01L 25/167; H10D 86/021; H10D 86/451; H10H 20/857; H10D 86/441; H10H 20/0364

(57) ABSTRACT

A stretchable display device includes a base substrate having a rigid portion and a soft portion; a stretchable line provided in the soft portion over the base substrate; a planarization layer provided in the rigid portion over the base substrate and having a first portion and a second portion of different heights; a light-emitting element over the first portion of the planarization layer; and an auxiliary light-emitting element over the second portion of the planarization layer, wherein a first height of the first portion of the planarization layer from the base substrate is greater than a second height of the second portion of the planarization layer from the base substrate.

### CROSS-REFERENCE TO RELATED APPLICATION

The present application claims priority to Republic of Korea Patent Application No. 10-2024-0027902 filed on Feb. 27, 2024, which is hereby incorporated by reference in its entirety.

### BACKGROUND

### Field of the Disclosure

The present disclosure relates to a display device, and more particularly, to a stretchable display device and a method of manufacturing the same.

### Discussion of the Background Art

As the information society progresses, interest in displays that process and display a large amount of information has been increasing, and various types of displays have been developed.

Accordingly, in addition to a commonly known rectangular display, flexible display devices such as a bendable display device for gaming, a foldable display device capable of being folded and unfolded, and a rollable display device having optimal space utilization have been widely developed.

Recently, a stretchable display device, which is much more flexible than these flexible display devices, has been in the spotlight as a next-generation display.

The stretchable display device is a display that can freely transform the shape of a screen without distortion even when the size of the screen is increased, folded, or twisted. Unlike the bendable, foldable, or rollable display devices that can only be transformed in a specific area or direction, the stretchable display device is able to implement the ultimate free-form and is considered as the most suitable display for the era of the Internet of Things (IoT), 5G, and autonomous vehicles.

The stretchable display device may include a rigid portion in which a pixel is disposed and a soft portion in which a connection line connecting the pixels is disposed. The rigid portion may not be stretched, and the soft portion may be stretched.

To display an image, the stretchable display device includes a light-emitting element in the rigid portion, and an anisotropic conductive film (ACF) may be used to fix and electrically connect the light-emitting element.

The anisotropic conductive film may include an insulating base member and a plurality of conductive balls dispersed in the insulating base member. The anisotropic conductive film may be transferred at once in response to a plurality of rigid portions using a transfer film. The anisotropic conductive film is transferred to the entire rigid portion, resulting in high consumption, and the manufacturing costs increase.

In addition, since there is substantially no step difference in the rigid portion, misalignment is likely to occur during the transfer process of the light-emitting element, and there is a problem that an electrical short circuit occurs between the misaligned light-emitting element on the anisotropic conductive film and the signal line and/or electrode.

### SUMMARY

Accordingly, the present disclosure is to provide a stretchable display device and a method of manufacturing the same that substantially obviates one or more of the limitations and disadvantages described above and associated with the background art.

More specifically, an object of the present disclosure is to provide a stretchable display device and a method of manufacturing the same capable of reducing the consumed amount of the anisotropic conductive film and decreasing the manufacturing costs.

Another object of the present disclosure is to provide a stretchable display device and a method of manufacturing the same capable of preventing the electrical short circuit.

Additional features and embodiments will be set forth in the description that follows, and in part will be apparent from the description, or can be learned by practice of the present disclosure provided herein. Other features and embodiments of the inventive concepts can be realized and attained by the structure particularly pointed out in the written description, or derivable therefrom, and the claims hereof as well as the appended drawings.

To achieve these and other embodiments of the present disclosure, as embodied and broadly described herein, a stretchable display device includes a base substrate having a rigid portion and a soft portion; a stretchable line provided in the soft portion over the base substrate; a planarization layer provided in the rigid portion over the base substrate and having a first portion and a second portion of different heights; a light-emitting element over the first portion of the planarization layer; and an auxiliary light-emitting element over the second portion of the planarization layer, wherein a first height of the first portion of the planarization layer from the base substrate is greater than a second height of the second portion of the planarization layer from the base substrate.

In another embodiment, a method of manufacturing a stretchable display device includes preparing a base substrate having a rigid portion and a soft portion; forming a planarization layer in the rigid portion over the base substrate, the planarization layer having a first portion and a second portion of different heights; forming a stretchable line in the soft portion over the base substrate; transferring an auxiliary light-emitting element over the second portion of the planarization layer; forming a conductive adhesive layer over the first portion of the planarization layer, transferring a light-emitting element on the conductive adhesive layer, wherein a first height of the first portion of the planarization layer from the base substrate is greater than a second height of the second portion of the planarization layer from the base substrate.

It is to be understood that both the foregoing general description and the following detailed description are examples and are intended to provide further explanation of the inventive concepts as claimed.

### BRIEF DESCRIPTION OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is a schematic cross-sectional view of a stretchable display device according to an embodiment of the present disclosure;

FIG. 2 is a schematic plan view of a display panel of a stretchable display device according to an embodiment of the present disclosure;

FIG. 3 is a plan view schematically illustrating a part of a display panel of a stretchable display device according to an embodiment of the present disclosure;

FIG. 4 is an equivalent circuit diagram for a sub-pixel of a stretchable display device according to an embodiment of the present disclosure;

FIG. 5 is a schematic cross-sectional view of a display panel of a stretchable display device corresponding to line I-I′ of FIG. 3 according to an embodiment of the present disclosure;

FIG. 6 is a schematic cross-sectional view of a display panel of a stretchable display device corresponding to line II-II′ of FIG. 3 according to an embodiment of the present disclosure;

FIG. 7 is a schematic cross-sectional view of a display panel of a stretchable display device corresponding to line III-III′ of FIG. 3 according to an embodiment of the present disclosure;

FIGS. 8A to 8F are schematic cross-sectional views of a display panel in steps of manufacturing a stretchable display device according to the embodiment of the present disclosure;

FIG. 9 is a schematic plan view of an anisotropic conductive film according to a comparative example;

FIG. 10 is a schematic plan view of a unit area of an anisotropic conductive film according to the comparative example; and

FIG. 11 is a schematic plan view of a unit area of an anisotropic conductive film according to an embodiment of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship.

Hereinafter, exemplary embodiments of the present disclosure will be described in detail with reference to accompanying drawings.

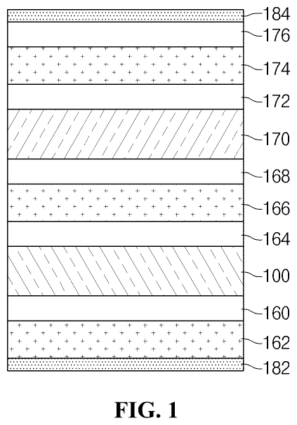

FIG. 1 is a schematic cross-sectional view of a stretchable display device according to an embodiment of the present disclosure.

In FIG. 1, a stretchable display device according to an embodiment of the present disclosure may include a display panel 100, a touch panel 170, a first flexible substrate 162, a second flexible substrate 166, a third flexible substrate 174, a first protection film 182, and a second protection film 184.

The display panel 100 may displays an image and may include a rigid portion provided with a pixel for implementing the image and a soft portion provided with a connection line connecting adjacent pixels, which will be described in detail later.

The first flexible substrate 162 may be disposed under the display panel 100 and may be provided with a first transparent adhesive layer 160 to thereby have a double film shape. The display panel 100 may be attached to the first flexible substrate 162 through the first transparent adhesive layer 160. In addition, the second flexible substrate 166 may be disposed over the display panel 100 and may be provided with a second transparent adhesive layer 164 at its bottom surface and a third transparent adhesive layer 168 at its top surface to thereby have a triple film shape. The display panel 100 may be attached to the second flexible substrate 166 through the second transparent adhesive layer 164.

The first flexible substrate 162 and the second flexible substrate 166 may be formed of a soft matter or soft material with bending or stretching properties. For example, the first flexible substrate 162 and the second flexible substrate 166 may be formed of silicone rubber such as polydimethylsiloxane (PDMS), elastomer such as polyurethane (PU), or styrene butadiene block copolymer such as styrene butadiene styrene (SBS).

The first flexible substrate 162 and the second flexible substrate 166 may be formed of the same material. However, embodiments of the present disclosure are not limited thereto. In other embodiments, the first flexible substrate 162 and the second flexible substrate 166 may be formed of different materials.

The first flexible substrate 162 and the second flexible substrate 166 may have relatively low elastic modulus, that is, Young's modulus, and may have a relatively high ductile breaking rate. Here, the elastic modulus is a value representing the rate of deformation relative to the stress applied to an object. If the elastic modulus is relatively high, the hardness may be relatively high. In addition, the ductile breaking rate refers to the elongation rate at the point when the stretched object is broken or cracked.

For example, each of the first flexible substrate 162 and the second flexible substrate 166 may have the elastic modulus of several MPa to hundreds of MPa and the ductile breaking rate of about 100% or more. In addition, each of the first flexible substrate 162 and the second flexible substrate 166 may have a thickness of about 10 μm to about 1 mm. However, embodiments of the present disclosure are not limited thereto.

Meanwhile, the first, second, and third transparent adhesive layers 160, 164, and 168 may be formed of an acryl-based, silicon-based, or urethane-based adhesive. For example, the first, second, and third transparent adhesive layers 160, 164, and 168 may be optically clear adhesive (OCA) that is formed and attached in the form of a film or optically clear resin (OCR) that is cured after applying a liquid material.

Next, the touch panel 170 may be disposed over the second flexible substrate 166 and may be attached to the second flexible substrate 166 through the third transparent adhesive layer 168.

The touch panel 170 may include a plurality of transmitter electrodes and a plurality of receiver electrodes and may detect a touch from a change in capacitance between the transmitter electrode and the receiver electrode.

The third flexible substrate 174 may be disposed over the touch panel 170 and may be provided with a fourth transparent adhesive layer 172 at its bottom surface and a fifth transparent adhesive layer 176 at its top surface. The touch panel 170 may be attached to the third flexible substrate 174 through the fourth transparent adhesive layer 172.

The third flexible substrate 174 may be formed of the same material as the first and second flexible substrates 162 and 166, and the fourth and fifth transparent adhesive layers 172 and 176 may be formed of the same material as the first, second, and third transparent adhesive layers 160, 164, and 168.

The first protection film 182 may be disposed under the first flexible substrate 162, and the second protection film 184 may be disposed over the third flexible substrate 174, thereby protecting the components of the stretchable display device. The second protection film 184 may be attached to the third flexible substrate 174 through the fifth transparent adhesive layer 176, and although not shown in the figure, a transparent adhesive layer may be provided and attached between the first flexible substrate 162 and the first protection film 182.

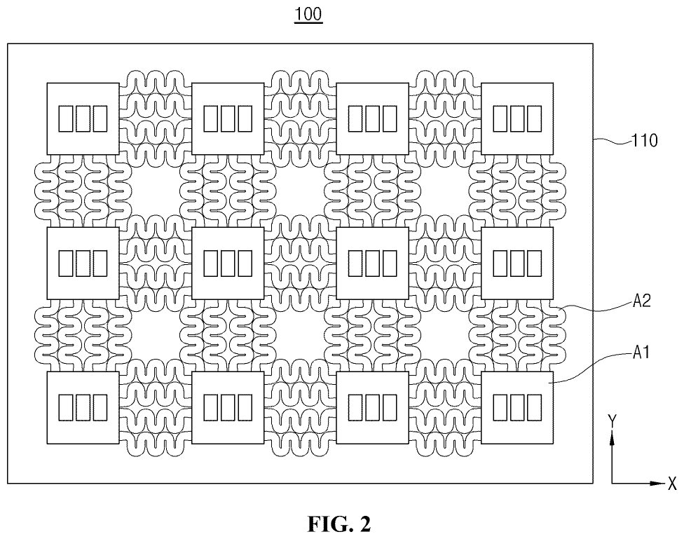

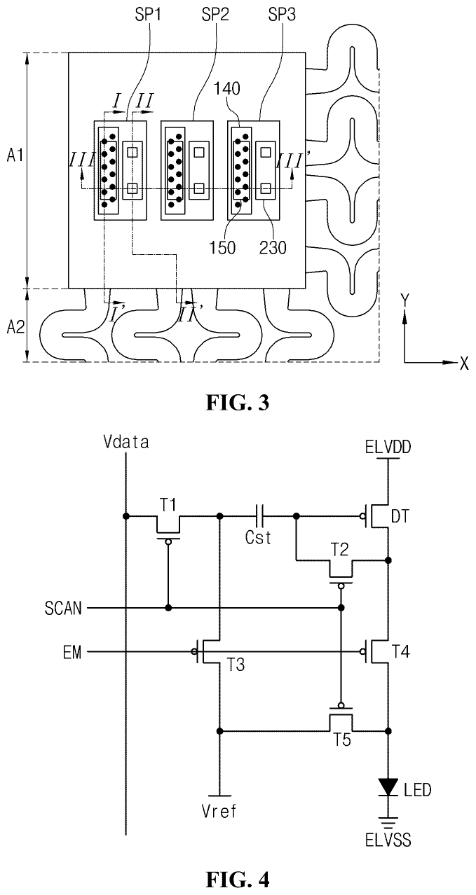

The planar configuration of the display panel of the stretchable display device will be described in detail with reference to FIG. 2 and FIG. 3.

FIG. 2 is a schematic plan view of a display panel of a stretchable display device according to an embodiment of the present disclosure, and FIG. 3 is a plan view schematically illustrating a part of a display panel of a stretchable display device according to an embodiment of the present disclosure.

In FIG. 2 and FIG. 3, the display panel 100 may be stretched in a first direction X and/or a second direction Y. The display panel 100 may include a base substrate 110, and a rigid portion A1 corresponding to a first area and a soft portion A2 corresponding to a second area may be provided on the base substrate 110. The rigid portion A1 may not be stretched, and the soft portion A2 may be stretched.

The rigid portion A1 may be provided in the form of an island, and a plurality of rigid portions A1 may be disposed to be spaced apart from each other along the first direction X and the second direction Y. For example, the rigid portion A1 may have a substantially rectangular shape. The rigid portions A1 may be arranged in a matrix form.

A pixel including a plurality of sub-pixels SP1, SP2, and SP3 may be provided in the rigid portion A1. For example, first, second, and third sub-pixels SP1, SP2, and SP3 may be provided in the rigid portion A1, and the first, second, and third sub-pixels SP1, SP2, and SP3 may be red, green, and blue sub-pixels, respectively.

Each of the plurality of sub-pixels SP1, SP2, and SP3 may include a light-emitting element, at least one thin film transistor, and at least one capacitor.

The soft portion A2 may be disposed between adjacent rigid portions A1 in each of the first direction X and the second direction Y. A stretchable line that is a connection line connecting the adjacent pixels may be provided in the soft portion A2. The stretchable line may include a plurality of voltage lines such as a gate line, a data line, a high potential line, a low potential line, an emission line, and a reference voltage line.

The stretchable line may have at least one curved part. For example, the stretchable line may have a wave structure and may include a plurality of wave shapes.

FIG. 4 is an equivalent circuit diagram for a sub-pixel of a stretchable display device according to an embodiment of the present disclosure.

In FIG. 4, one sub-pixel of the stretchable display device according to the embodiment of the present disclosure, that is, each of the first, second, and third sub-pixels SP1, SP2, and SP3 may include a driving transistor DT, first, second, third, fourth, and fifth transistors T1, T2, T3, T4, and T5, a storage capacitor Cst, and a light-emitting diode LED.

For example, the driving transistor DT and the first, second, third, fourth, and fifth transistors T1, T2, T3, T4, and T5 may be P-type transistors. However, embodiments of the present disclosure are not limited thereto. In other embodiments, the driving transistor DT and the first, second, third, fourth, and fifth transistors T1, T2, T3, T4, and T5 may be N-type transistors.

The driving transistor DT may be switched according to a voltage of a first capacitor electrode of the storage capacitor Cst and may be connected to a high potential voltage ELVDD. Specifically, a gate of the driving transistor DT may be connected to the first capacitor electrode of the storage capacitor Cst and a source of the second transistor T2. A source of the driving transistor DT may be connected to the high potential voltage ELVDD. A drain of the driving transistor DT may be connected to a drain of the second transistor T2 and a source of the fourth transistor T4.

The first transistor T1 may be switched on or off according to a gate signal SCAN and may be connected to a data signal Vdata. Specifically, a gate of the first transistor T1 may be connected to the gate signal SCAN. A source of the first transistor T1 may be connected to the data signal Vdata. A drain of the first transistor T1 may be connected to a second capacitor electrode of the storage capacitor Cst and a source of the third transistor T3.

The second transistor T2 may be switched on or off according to the gate signal SCAN and may be connected to the driving transistor DT. Specifically, a gate of the second transistor T2 may be connected to the scan signal SCAN. The source of the second transistor T2 may be connected to the first capacitor electrode of the storage capacitor Cst and the gate of the driving transistor DT. The drain of the second transistor T2 may be connected to the source of the driving transistor DT and the source of the fourth transistor T4.

The third transistor T3 may be switched on or off according to an emission signal EM and may be connected to a reference voltage Vref. A gate of the third transistor T3 may be connected to the emission signal EM. The source of the third transistor T3 may be connected to the second capacitor electrode of the storage capacitor Cst and the drain of the first transistor T1. A drain of the third transistor T3 may be connected to the reference voltage Vref and a source of the fifth transistor T5.

The fourth transistor T4 may be switched on or off according to the emission signal EM and may be connected to the driving transistor DT and the light-emitting diode LED. Specifically, a gate of the fourth transistor T4 may be connected to the emission signal EM. The source of the fourth transistor T4 may be connected to the drain of the driving transistor DT and the drain of the second transistor T2. A drain of the fourth transistor T4 may be connected to a drain of the fifth transistor T5 and a first electrode of the light-emitting diode LED.

The fifth transistor T5 may be switched on or off according to the gate signal SCAN and may be connected to the reference voltage Vref and the fourth transistor T4. Specifically, a gate of the fifth transistor T5 may be connected to the scan signal SCAN. The source of the fifth transistor T5 may be connected to the reference voltage Vref and the drain of the third transistor T3. The drain of the fifth transistor T5 may be connected to the drain of the fourth transistor T4 and the first electrode of the light-emitting diode LED.

The storage capacitor Cst may store the data signal Vdata and a threshold voltage Vth of the driving transistor DT. The first capacitor electrode of the storage capacitor Cst may be connected to the gate of the driving transistor DT and the source of the second transistor T2. The second capacitor electrode of the storage capacitor Cst may be connected to the drain of the first transistor T1 and the source of the third transistor T3.

The light-emitting diode LED may be connected between the fourth and fifth transistors T4 and T5 and a low potential voltage ELVSS and may emit light with luminance proportional to a current of the driving transistor DT. The first electrode of the light-emitting diode LED, which is an anode, may be connected to the drain of the fourth transistor T4 and the drain of the fifth transistor T5. The second electrode of the light-emitting diode LED, which is a cathode, may be connected to the low potential voltage ELVSS.

In the embodiment of the present disclosure of FIG. 4, as an example, each sub-pixel has a 6TIC structure including six transistors and one capacitor, but in other embodiments, each sub-pixel may have one of 2TIC, 3TIC, 4TIC, 5TIC, 3T2C, 4T2C, 5T2C, 6T2C, 7TIC, 7T2C, 8TIC, and 8T2C structures.

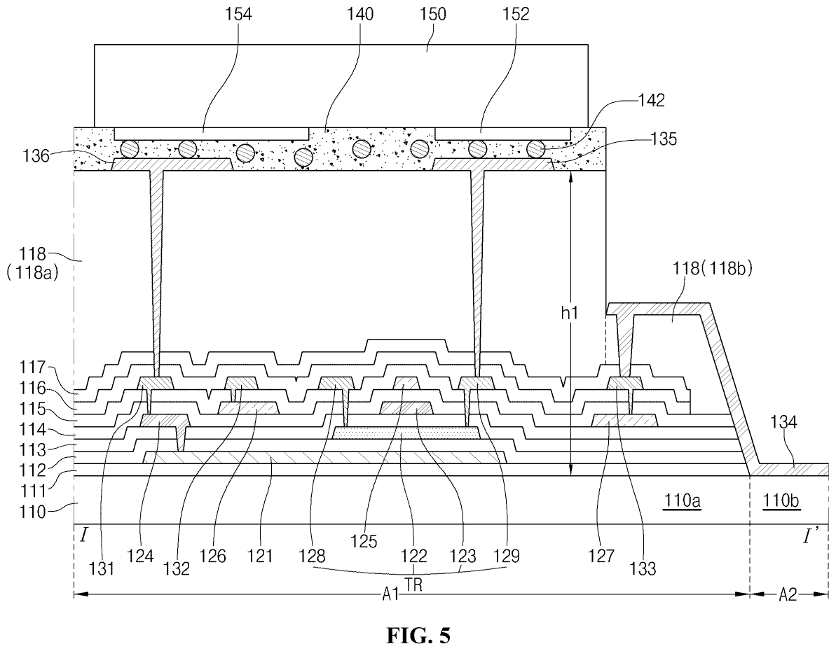

A cross-sectional structure of a stretchable display device according to an embodiment of the present disclosure will be described in detail with reference to FIGS. 5 to 7.

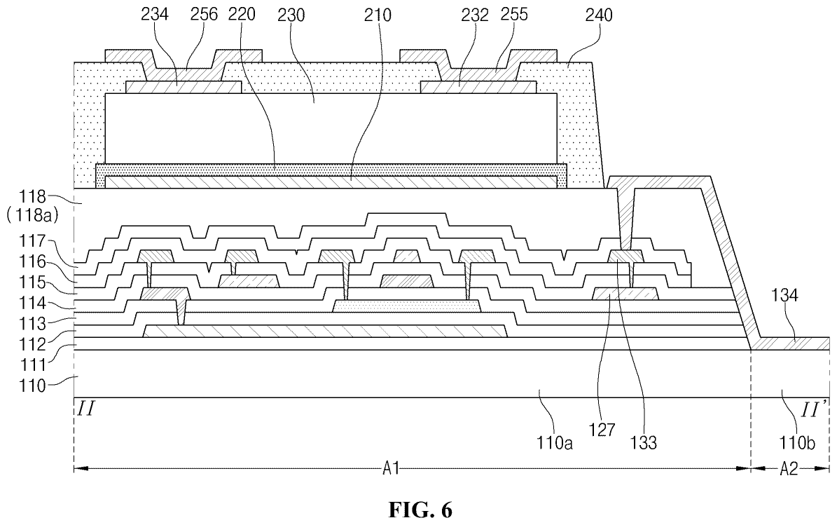

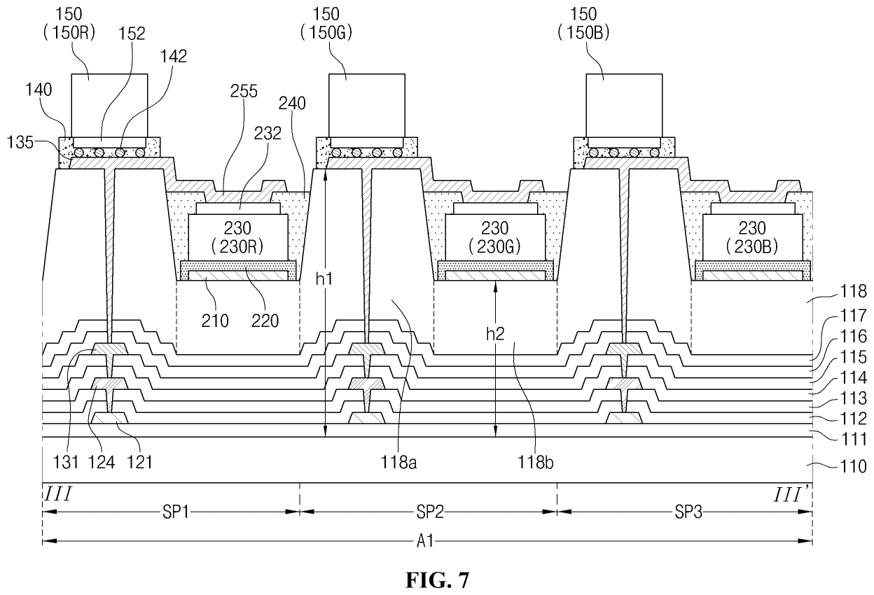

FIGS. 5 to 7 are schematic cross-sectional views of a display panel of a stretchable display device according to an embodiment of the present disclosure. FIG. 5 shows a cross-section corresponding to line I-I′ of FIG. 3 according to an embodiment of the present disclosure, FIG. 6 shows a cross-section corresponding to line II-II′ of FIG. 3 according to an embodiment of the present disclosure, and FIG. 7 shows a cross-section corresponding to line III-III′ of FIG. 3 according to an embodiment of the present disclosure.

In FIG. 5, FIG. 6, and FIG. 7, the display panel 100 of the stretchable display device according to the embodiment of the present disclosure may include a base substrate 110 provided with a rigid portion A1 and a soft portion A2.

The base substrate 110 may include a first base portion 110a and a second base portion 110b. The first base portion 110a may be disposed to correspond to the rigid portion A1, and the second base portion 110b may be disposed to correspond to the soft portion A2.

The first base portion 110a may be provided in a plate shape in a display area and may serve to support and protect components of the first, second, and third sub-pixels SP1, SP2, and SP3. The first base portion 110a may be plural, and the plurality of first base portions 110a may be spaced apart from each other in the first direction X and the second direction Y.

The second base portion 110b may be provided between adjacent first base portions 110a. The second base portion 110b may include at least one curved part and may serve to support and protect a stretchable line 134.

The first and second base portions 110a and 110b may be connected to each other and may be provided as one-body.

The base substrate 110 may be formed of a rigid material having lower flexibility than the soft material of the first and second flexible substrates 162 and 166. For example, the base substrate 110 may be formed of a polyimide (PI) resin or epoxy resin.

The base substrate 110 may have relatively high elastic modulus, and the elastic modulus of the base substrate 110 may be higher than the elastic modulus of the first and second flexible substrates 162 and 166. For example, the elastic modulus of the base substrate 110 may be more than 1,000 times higher than the elastic modulus of the first and second flexible substrates 162 and 166, but embodiments of the present disclosure are not limited thereto.

A first buffer layer 111 may be provided on the base substrate 110 as a first insulation layer. The first buffer layer 111 may block permeation of moisture or oxygen from the outside to protect the components of the plurality of sub-pixels SP1, SP2, and SP3.

The first buffer layer 111 may be formed as a single layer or multiple layers of an inorganic insulating material. The inorganic insulating material of the first buffer layer 111 may include silicon nitride (SiNx), silicon oxide (SiOx), or silicon oxynitride (SiON).

To prevent damage of the first buffer layer 111 such as cracks due to stretching, the first buffer layer 111 may be removed in the soft portion A2 to substantially correspond to the rigid portion A1, so that the first buffer layer 111 may be provided over the first base portion 110a of the base substrate 110 and may not be provided over the second base portion 110b.

In other embodiments, the first buffer layer 111 may be omitted.

A light shielding layer 121 may be provided on the first buffer layer 111 of the rigid portion A1. The light shielding layer 121 may be formed of a conductive material such as metal. For example, the light shielding layer 121 may be formed of at least one of aluminum (Al), copper (Cu), molybdenum (Mo), titanium (Ti), chromium (Cr), nickel (Ni), tungsten (W), or an alloy thereof. The light shielding layer 121 may have a single-layered structure or a multiple-layered structure.

A second buffer layer 112 may be provided on the light shielding layer 121 as a second insulation layer. The second buffer layer 112 may be formed as a single layer or multiple layers of an inorganic insulating material. The inorganic insulating material of the second buffer layer 112 may include silicon nitride (SiNx), silicon oxide (SiOx), or silicon oxynitride (SiON).

To prevent or at least reduce damage of the second buffer layer 112 such as cracks due to stretching, the second buffer layer 112 may be removed in the soft portion A2 to substantially correspond to the rigid portion A1. The second buffer layer 112 may be provided over the first base portion 110a of the base substrate 110 and may not be provided over the second base portion 110b.

A semiconductor layer 122 may be provided on the second buffer layer 112. The semiconductor layer 122 may overlap the light shielding layer 121, and the light shielding layer 121 may block light incident on the semiconductor layer 122 and prevent the semiconductor layer 122 from deteriorating due to the light.

The semiconductor layer 122 may include a channel region at its central part and source and drain regions at both sides of the channel region.

The semiconductor layer 122 may be formed of an oxide semiconductor material. Alternatively, the semiconductor layer 122 may be formed of polycrystalline silicon, and in this case, both ends of the semiconductor layer 122 may be doped with impurities.

A gate insulation layer 113 may be provided on the semiconductor layer 122 as a third insulation layer. The gate insulation layer 113 may be formed as a single layer or multiple layers of an inorganic insulating material. The inorganic insulating material of the gate insulation layer 113 may include silicon nitride (SiNx), silicon oxide (SiOx), or silicon oxynitride (SiON).

To prevent or at least reduce damage of the gate insulation layer 113 such as cracks due to stretching, the gate insulation layer 113 may be removed in the soft portion A2 to substantially correspond to the rigid portion A1. The gate insulation layer 113 may be provided over the first base portion 110a of the base substrate 110 and may not be provided over the second base portion 110b.

A gate electrode 123 and a first connection electrode 124 may be provided on the gate insulation layer 113.

The gate electrode 123 may overlap the semiconductor layer 122 and may be disposed to correspond to the central part of the semiconductor layer 122. Accordingly, the gate electrode 123 may also overlap the light shielding layer 121.

The first connection electrode 124 may be spaced apart from the semiconductor layer 122 and may overlap the light shielding layer 121. The first connection electrode 124 may be in contact with the light shielding layer 124 through a contact hole provided in the second buffer layer 112 and the gate insulation layer 113.

The gate electrode 123 and the first connection electrode 124 may be formed of a conductive material such as metal. For example, the gate electrode 123 and the first connection electrode 124 may be formed of at least one of aluminum (Al), copper (Cu), molybdenum (Mo), titanium (Ti), chromium (Cr), nickel (Ni), tungsten (W), or an alloy thereof. The gate electrode 123 and the first connection electrode 124 may have a single-layered structure or a multiple-layered structure.

A first interlayer insulation layer 114 may be provided on the gate electrode 123 and the first connection electrode 124 as a fourth insulation layer. The first interlayer insulation layer 114 may be formed as a single layer or multiple layers of an inorganic insulating material. The inorganic insulating material of the first interlayer insulation layer 114 may include silicon nitride (SiNx), silicon oxide (SiOx), or silicon oxynitride (SiON).

To prevent or at least reduce damage of the first interlayer insulation layer 114 such as cracks due to stretching, the first interlayer insulation layer 114 may be removed in the soft portion A2 to substantially correspond to the rigid portion A1. The first interlayer insulation layer 114 may be provided over the first base portion 110a of the base substrate 110 and may not be provided over the second base portion 110b.

An auxiliary electrode 125, an auxiliary line 126, and a pad electrode 127 may be provided on the first interlayer insulation layer 114. The auxiliary electrode 125 may overlap gate electrode 123, the semiconductor layer 122, and the light shielding layer 121. The auxiliary line 126 may overlap the light shielding layer 121 and may be spaced apart from the gate electrode 123, the semiconductor layer 122, and the first connection electrode 124. The pad electrode 127 may be spaced apart from the light shielding layer 121 and may be disposed close to an edge of the rigid portion A1 adjacent to the soft portion A2.

The auxiliary electrode 125, the auxiliary line 126, and the pad electrode 127 may be formed of a conductive material such as metal. For example, the auxiliary electrode 125, the auxiliary line 126, and the pad electrode 127 may be formed of at least one of aluminum (Al), copper (Cu), molybdenum (Mo), titanium (Ti), chromium (Cr), nickel (Ni), tungsten (W), or an alloy thereof. The auxiliary electrode 125, the auxiliary line 126, and the pad electrode 127 may have a single-layered structure or a multiple-layered structure.

A second interlayer insulation layer 115 may be provided on the auxiliary electrode 125, the auxiliary line 126, and the pad electrode 127 as a fifth insulation layer. The second interlayer insulation layer 115 may be formed as a single layer or multiple layers of an inorganic insulating material. The inorganic insulating material of the second interlayer insulation layer 115 may include silicon nitride (SiNx), silicon oxide (SiOx), or silicon oxynitride (SiON).

To prevent or at least reduce damage of the second interlayer insulation layer 115 such as cracks due to stretching, the second interlayer insulation layer 115 may be removed in the soft portion A2 to substantially correspond to the rigid portion A1. The second interlayer insulation layer 115 may be provided over the first base portion 110a of the base substrate 110 and may not be provided over the second base portion 110b.

A source electrode 128, a drain electrode 129, a second connection electrode 131, and a power line 132 may be provided on the second interlayer insulation layer 115.

The source electrode 128 and the drain electrode 129 may be spaced apart from each other with the gate electrode 123 positioned therebetween and may be in contact with both ends of the semiconductor layer 122 through contact holes provided in the first and second interlayer insulation layers 114 and 115 and the gate insulation layer 113. The gate electrode 123 and the auxiliary electrode 125 may be disposed between the source electrode 128 and the drain electrode 129.

The semiconductor layer 122, the gate electrode 123, the source electrode 128, and the drain electrode 129 may constitute a thin film transistor TR.

The second connection electrode 131 may be spaced apart from the thin film transistor TR. The second connection electrode 131 may overlap the first connection electrode 124 and may be in contact with the first connection electrode 124 through a contact hole provided in the first and second interlayer insulation layers 114 and 115. In addition, the second connection electrode 131 may overlap the light shielding layer 121.

The power line 132 may be spaced apart from the thin film transistor TR. The power line 132 may overlap the auxiliary line 126 and may be in contact with the auxiliary line 126 through a contact hole formed in the second interlayer insulation layer 115.

For example, the power line 132 may be a line supplying the low potential voltage ELVSS. In this case, the power line 132 or the auxiliary line 126 may be connected to the light shielding layer 121. That is, the light shielding layer 121 may be supplied with the low potential voltage ELVSS.

The source electrode 128, the drain electrode 129, the second connection electrode 131, and the power line 132 may be formed of a conductive material such as metal. For example, the source electrode 128, the drain electrode 129, the second connection electrode 131, and the power line 132 may be formed of at least one of aluminum (Al), copper (Cu), molybdenum (Mo), titanium (Ti), chromium (Cr), nickel (Ni), tungsten (W), or an alloy thereof. The source electrode 128, the drain electrode 129, the second connection electrode 131, and the power line 132 may have a single-layered structure or a multiple-layered structure.

A third interlayer insulation layer 116 may be provided on the source electrode 128, the drain electrode 129, the second connection electrode 131, and the power line 132 as a sixth insulation layer. The third interlayer insulation layer 116 may be formed as a single layer or multiple layers of an inorganic insulating material. The inorganic insulating material of the third interlayer insulation layer 116 may include silicon nitride (SiNx), silicon oxide (SiOx), or silicon oxynitride (SiON).

To prevent or at least reduce damage of the third interlayer insulation layer 116 such as cracks due to stretching, the third interlayer insulation layer 116 may be removed in the soft portion A2 to substantially correspond to the rigid portion A1. The third interlayer insulation layer 116 may be provided over the first base portion 110a of the base substrate 110 and may not be provided over the second base portion 110b.

An auxiliary pad 133 may be provided on the third interlayer insulation layer 116. The auxiliary pad 133 may overlap the pad electrode 127 and may be in contact with the pad electrode 127 through a contact hole provided in the second and third interlayer insulation layers 115 and 116.

The auxiliary pad 133 may be formed of a conductive material such as metal. For example, the auxiliary pad 133 may be formed of at least one of aluminum (Al), copper (Cu), molybdenum (Mo), titanium (Ti), chromium (Cr), nickel (Ni), tungsten (W), or an alloy thereof. The auxiliary pad 133 may have a single-layered structure or a multiple-layered structure.

A passivation layer 117 may be provided on the auxiliary pad 133. The passivation layer 117 may be formed as a single layer or multiple layers of an inorganic insulating material. The inorganic insulating material of the passivation layer 117 may include silicon nitride (SiNx), silicon oxide (SiOx), or silicon oxynitride (SiON).

To prevent or at least reduce damage of the passivation layer 117 such as cracks due to stretching, the passivation layer 117 may be removed in the soft portion A2 to substantially correspond to the rigid portion A1. The passivation layer 117 may be provided over the first base portion 110a of the base substrate 110 and may not be provided over the second base portion 110b.

In this case, edges of the passivation layer 117 and the third interlayer insulation layer 116 of the rigid portion A1 adjacent to the soft portion A2 may be partially removed, thereby exposing a top surface of the second interlayer insulation layer 115.

The passivation layer 117 may be omitted.

A planarization layer 118 may be provided on the passivation layer 117. The planarization layer 118 may eliminate a step difference due to the layers thereunder and may have a substantially flat top surface. The planarization layer 118 may be formed of an organic insulating material such as photosensitive acrylic polymer (photo acryl).

The planarization layer 118 may be provided in the rigid portion A1 and may not be provided in the soft portion A2. Accordingly, the planarization layer 118 may be provided over the first base portion 110a of the base substrate 110 and may not be provided over the second base portion 110b.

In the rigid portion A1, the planarization layer 118 may be in contact with side surfaces of the third interlayer insulation layer 116 and the passivation layer 117 and be in contact with the exposed top surface of the second interlayer insulation layer 115.

The planarization layer 118 may include a first portion 118a and a second portion 118b.

Specifically, the first portion 118a may have a first height h1 from the base substrate 110, and the second portion 118b may have a second height h2 from the base substrate 110. The first height h1 may be higher than the second height h2. A difference between the first height h1 and the second height h2 may be greater than a thickness of an auxiliary light-emitting element 230. In addition, the first portion 118a of the planarization layer 118 may have a thicker thickness than the second portion 118b. The first portion 118a and the second portion 118b of the planarization layer 118 may be provided in each of the first, second, and third sub-pixels SP1, SP2, and SP3. Further, the second portion 118b of the planarization layer 118 may be provided in the rigid portion A1 excluding the first, second, and third sub-pixels SP1, SP2, and SP3.

A first electrode 135 and a second electrode 136 may be provided on the planarization layer 118. The first electrode 135 and the second electrode 136 may be disposed on the first portion 118a of the planarization layer 118.

The first electrode 135 may overlap the drain electrode 129 and may be in contact with the drain electrode 129 through a contact hole provided in the planarization layer 118, the passivation layer 117, and the third interlayer insulation layer 116. The second electrode 136 may overlap the second connection electrode 131 and may be in contact with the second connection electrode 131 through a contact hole provided in the planarization layer 118, the passivation layer 117, and the third interlayer insulation layer 116.

The first electrode 135 and the second electrode 136 may be formed of a conductive material such as metal. For example, the first electrode 135 and the second electrode 136 may be formed of at least one of aluminum (Al), copper (Cu), molybdenum (Mo), titanium (Ti), chromium (Cr), nickel (Ni), tungsten (W), or an alloy thereof. The first electrode 135 and the second electrode 136 may have a single-layered structure or a multiple-layered structure.

In addition, the stretchable line 134 may be provided on the planarization layer 118. In this case, the stretchable line 134 may be disposed on the second portion 118b of the planarization layer 118.

An end of the stretchable line 134 may be disposed on the planarization layer 118 of the rigid portion A1, that is, on the second portion 118b of the planarization layer 118. The end of the stretchable line 134 may overlap the auxiliary pad 133 and may be in contact with the auxiliary pad 133 through a contact hole provided in the planarization layer 118 and the passivation layer 117. The end of the stretchable line 134 may also overlap the pad electrode 127.

The stretchable line 134 may extend into and be provided in the soft portion A2. The stretchable line 134 may be in contact with a top surface of the second base portion 110b in the soft portion A2. The stretchable line 134 may be in contact with side surfaces of the first buffer layer 111, the second buffer layer 112, the gate insulation layer 113, the first interlayer insulation layer 114, the second interlayer insulation layer 115, and the planarization layer 118.

The stretchable line 134 may be formed of a conductive material such as metal. For example, the stretchable line 134 may be formed of at least one of aluminum (Al), copper (Cu), molybdenum (Mo), titanium (Ti), chromium (Cr), nickel (Ni), tungsten (W), or an alloy thereof. The stretchable line 134 may have a single-layered structure or a multiple-layered structure.

The stretchable line 134 may be formed of the same material as the first electrode 135 and the second electrode 136. However, embodiments of the present disclosure are not limited thereto.

In addition, a reflection layer 210 may be provided on the planarization layer 118. In this case, the reflection layer 210 may be disposed on the second portion 118b of the planarization layer 118.

The reflection layer 210 may be spaced apart from the stretchable line 134 on the second portion 118b of the planarization layer 118. The reflection layer 210 may be formed of a material having relatively high reflectance. The reflection layer 210 may be formed of the same material as the stretchable line 134. Alternatively, the reflection layer 210 may be formed of a different material from the stretchable line 134.

Meanwhile, the location of the reflection layer 210 may vary. For example, the reflection layer 210 may be provided between the base substrate 110 and the planarization layer 118.

In other embodiments, the reflection layer 210 may be omitted.

Next, an adhesive layer 220 may be provided on the reflection layer 210. In this case, the adhesive layer 220 may be disposed on the second portion 118b of the planarization layer 118. The adhesive layer 220 may cover top and side surfaces of the reflection layer 210 and be in contact with the top surface of the second portion 118b of the planarization layer 118.

The adhesive layer 220 may have a substantially flat top surface and may be formed of an organic insulating material having adhesiveness. That is, the adhesive layer 220 may have an insulating property. For example, the adhesive layer 220 may be formed of photosensitive acrylic polymer (photo acryl), but embodiments of the present disclosure are not limited thereto. In other embodiments, the adhesive layer 220 may be formed of an acryl-based, silicon-based, or urethane-based organic material.

The auxiliary light-emitting element 230 may be provided on the adhesive layer 220. The auxiliary light-emitting element 230 may be disposed over the second portion 118b of the planarization layer 118 and may overlap the reflection layer 210. Here, the width and area of the reflection layer 210, preferably, may be equal to or greater than the width and area of the auxiliary light-emitting element 230.

When the first, second, and third sub-pixels SP1, SP2, and SP3 are red, green, and blue sub-pixels, respectively, a red auxiliary light-emitting element 230R may be provided in the first sub-pixel SP1, a green auxiliary light-emitting element 230G may be provided in the second sub-pixel SP2, and a blue auxiliary light-emitting element 230B may be provided in the third sub-pixel SP3.

The auxiliary light-emitting element 230 may include a first auxiliary element electrode 232 and a second auxiliary element electrode 234. Here, the first auxiliary element electrode 232 may be a p-electrode, and the second auxiliary element electrode 234 may be an n-electrode. The first auxiliary element electrode 232 may be an anode, and the second auxiliary element electrode 234 may be a cathode. However, embodiments of the present disclosure are not limited thereto.

Alternatively, in other embodiments, the first auxiliary element electrode 232 may be an n-electrode, and the second auxiliary element electrode 234 may be a p-electrode. In this case, the first auxiliary element electrode 232 may be a cathode, and the second auxiliary element electrode 234 may be an anode.

The auxiliary light-emitting element 230 may be provided in the form of a micro light-emitting diode chip (micro-LED chip or uLED chip) including the n-electrode, an n-type layer, an active layer, a p-type layer, and the p-electrode. The auxiliary light-emitting element 230 may have a lateral structure in which the n-electrode and the p-electrode are provided on the same side (e.g., a side opposite to a side facing the base substrate 110) and light is emitted through the same side provided with the n-electrode and the p-electrode (e.g., the side opposite to the side facing the base substrate 110). Accordingly, the first auxiliary element electrode 232 and the second auxiliary element electrode 234 may be provided on the side opposite to the side facing the base substrate 110.

A protection layer 240 may be provided on the auxiliary light-emitting element 230. The protection layer 240 may be disposed on the second portion 118b of the planarization layer 118 and may cover and protect the auxiliary light-emitting element 230. The protection layer 240 may be in contact with top and side surfaces of the auxiliary light-emitting element 230 and may expose the first and second auxiliary element electrodes 232 and 234.

The protection layer 240 may have a substantially flat top surface and may be in contact with the top surface of the second portion 118b of the planarization layer 118. In addition, the protection layer 240 may be in contact with the side surface of the first portion 118a of the planarization layer 118 and may be spaced apart from the top surface of the first portion 118a of the planarization layer 118.

A height of the protection layer 240 from the base substrate 110 may be smaller than the height of the first portion 118a of the planarization layer 118, that is, the first height h1. In other words, the first height h1 of the first portion 118a of the planarization layer 118 from the base substrate 110 may be greater than the height of the protection layer 240, and thus the first height h1 may also be greater than the height of the auxiliary light-emitting element 230. For example, the difference between the first height h1 and the height of the protection layer 240 may be 1 μm to 2 μm, but embodiments of the present disclosure are not limited thereto.

The protection layer 240 may be formed of an organic insulating material the same as the planarization layer 118 and the adhesive layer 220. For example, the protection layer 240 may be formed of photosensitive acrylic polymer (photo acryl). However, embodiments of the present disclosure are not limited thereto. In other embodiments, the protection layer 240 may be formed of an organic insulating material different from the planarization layer 118 and the adhesive layer 220.

A first contact electrode 255 and a second contact electrode 256 may be provided on the protection layer 240. The first contact electrode 255 may be in contact with the first auxiliary element electrode 232 through a contact hole formed in the protection layer 240, and the second contact electrode 256 may be in contact with the second auxiliary element electrode 234 through a contact hole formed in the protection layer 240.

The first contact electrode 255 and the second contact electrode 256 may be formed of the same material and through the same process as the first electrode 135 and the second electrode 136. In this case, the first contact electrode 255 may be connected to the first electrode 135 to be formed as one body, and the second contact electrode 256 may be connected to the second electrode 136 to be formed as one body.

Accordingly, the first auxiliary element electrode 232 of the auxiliary light-emitting element 230 may be electrically connected to the first electrode 135 through the first contact electrode 255, and the second auxiliary element electrode 234 of the auxiliary light-emitting element 230 may be electrically connected to the second electrode 136 through the second contact electrode 256.

Next, a conductive adhesive layer 140 may be provided on the first electrode 135 and the second electrode 136. The conductive adhesive layer 140 may be disposed on the first portion 118a of the planarization layer 118 and may be in contact with the top surface of the first portion 118a of the planarization layer 118. The conductive adhesive layer 140 may not be provided on the second portion 118b of the planarization layer 118.

The conductive adhesive layer 140 may be formed of a different material from the adhesive layer 220. For example, the conductive adhesive layer 140 may be an anisotropic conductive film (ACF) including an insulating base member and a plurality of conductive balls 142 dispersed in the insulating base member, among others. When heat or pressure is applied to the conductive adhesive layer 140, the conductive balls 142 may be electrically connected in an area where the heat or pressure is applied, so that the conductive adhesive layer 140 may have a conductive property. In an area where the heat or pressure is not applied, the conductive adhesive layer 140 may have an insulating property.

A light-emitting element 150 may be provided on the conductive adhesive layer 140. The light-emitting element 150 may be disposed over the first portion 118a of the planarization layer 118.

When the first, second, and third sub-pixels SP1, SP2, and SP3 are the red, green, and blue sub-pixels, respectively, a red light-emitting element 150R may be provided in the first sub-pixel SP1, a green light-emitting element 150G may be provided in the second sub-pixel SP2, and a blue light-emitting element 150B may be provided in the third sub-pixel SP3.

The light-emitting element 150 may include a first element electrode 152 and a second element electrode 154. Here, the first element electrode 152 may be a p-electrode, and the second element electrode 154 may be an n-electrode. The first element electrode 152 may be an anode, and the second element electrode 154 may be a cathode. However, embodiments of the present disclosure are not limited thereto.

Alternatively, in other embodiments, the first element electrode 152 may be an n-electrode, and the second element electrode 154 may be a p-electrode. In this case, the first element electrode 152 may be a cathode, and the second element electrode 154 may be an anode.

The light-emitting element 150 may be provided in the form of a micro light-emitting diode chip (micro-LED chip or uLED chip) including the n-electrode, an n-type layer, an active layer, a p-type layer, and the p-electrode. The light-emitting element 150 may have a flip-chip structure in which the n-electrode and the p-electrode are provided on the same side (e.g., the side facing the base substrate 110) and light is emitted through a side opposite to the side provided with the n-electrode and the p-electrode (e.g., the side opposite to the side facing the base substrate 110).

The first element electrode 152 of the light-emitting element 150 may overlap the first electrode 135, and the second element electrode 154 of the light-emitting element 150 may overlap the second electrode 136. The first element electrode 152 may be electrically connected to the first electrode 135 through the conductive balls 142 of the conductive adhesive layer 140, and the second element electrode 154 may be electrically connected to the second electrode 136 through the conductive balls 142 of the conductive adhesive layer 140. Accordingly, the first element electrode 152 may be electrically connected to the drain electrode 129 of the thin film transistor TR through the first electrode 135, and the second element electrode 154 may be electrically connected to the low potential voltage ELVSS through the second electrode 136.

In addition, the first auxiliary element electrode 232 of the auxiliary light-emitting element 230, which is electrically connected to the first electrode 135 through the first contact electrode 255, may also be electrically connected to the drain electrode 129 of the thin film transistor TR. The second auxiliary element electrode 234 of the auxiliary light-emitting element 230, which is electrically connected to the second electrode 136 through the second contact electrode 256, may also be electrically connected to the low potential voltage ELVSS.

As such, in the stretchable display device according to the embodiment of the present disclosure, the planarization layer 118 having the first portion 118a and the second portion 118b of different heights may be provided, and the conductive adhesive layer 140 may be formed only on the first portion 118a of the planarization layer 118, which is relatively high due to the step difference. Accordingly, since the consumed amount of the anisotropic conductive film is reduced, the manufacturing costs can be decreased. The electrical short circuit between the light-emitting element 150 and the signal line and/or electrode can be prevented, even if the light-emitting element 150 is misaligned during the transfer process of the light-emitting element 150.

In addition, the auxiliary light-emitting element 230 may be further provided on the second portion 118b of the planarization layer 118, which is relatively low, and an image may be displayed by not only the light-emitting element 150 but also the auxiliary light-emitting element 230, so that the brightness can be improved.

Further, even if the light-emitting element 150 is defective, the image can be implemented by the auxiliary light-emitting element 230 after removing the defective light-emitting element 150, so that the defect can be repaired and the lifetime of the display device can be increased.

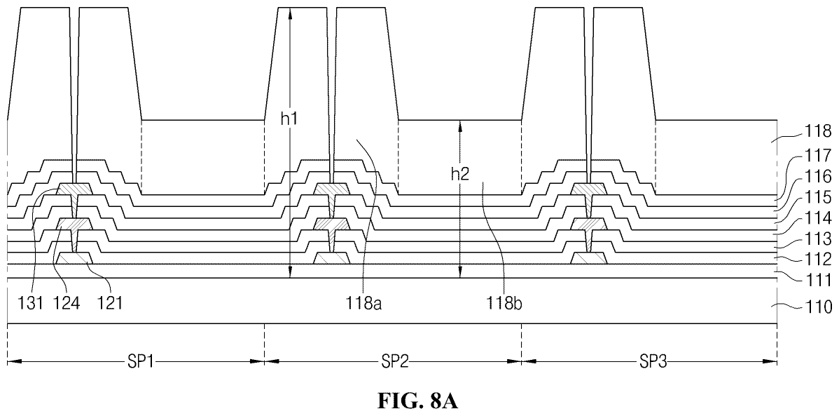

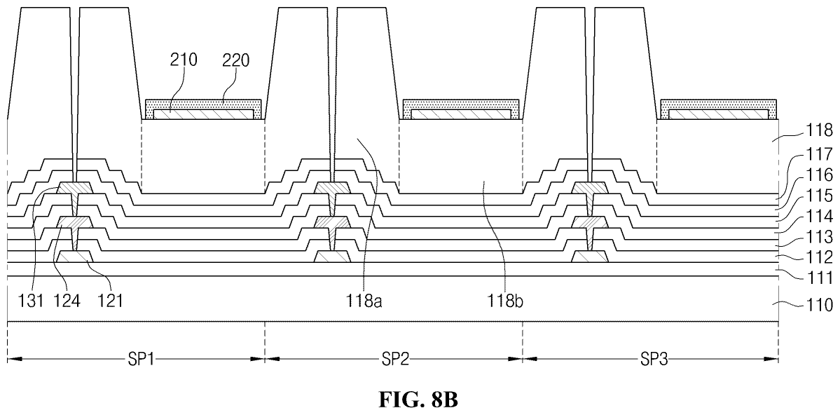

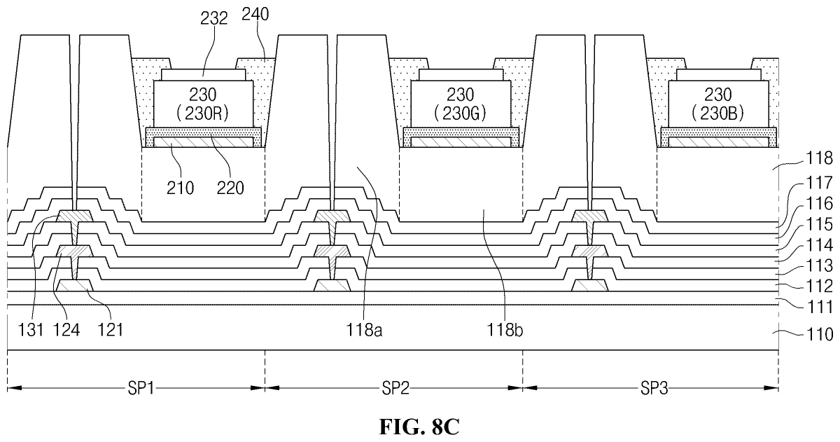

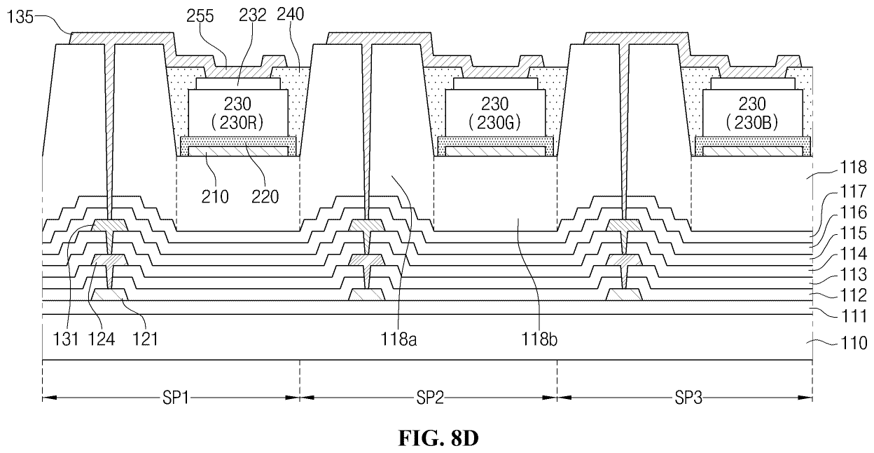

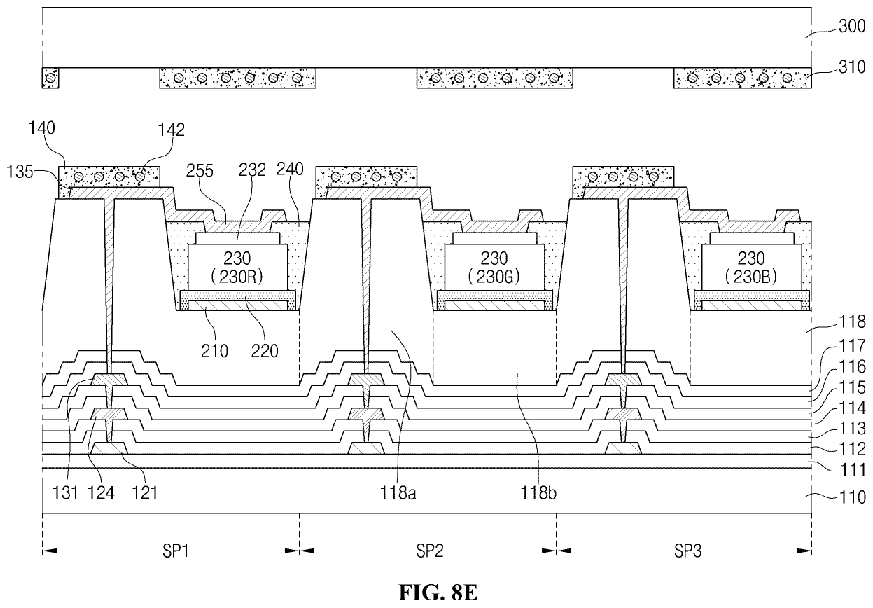

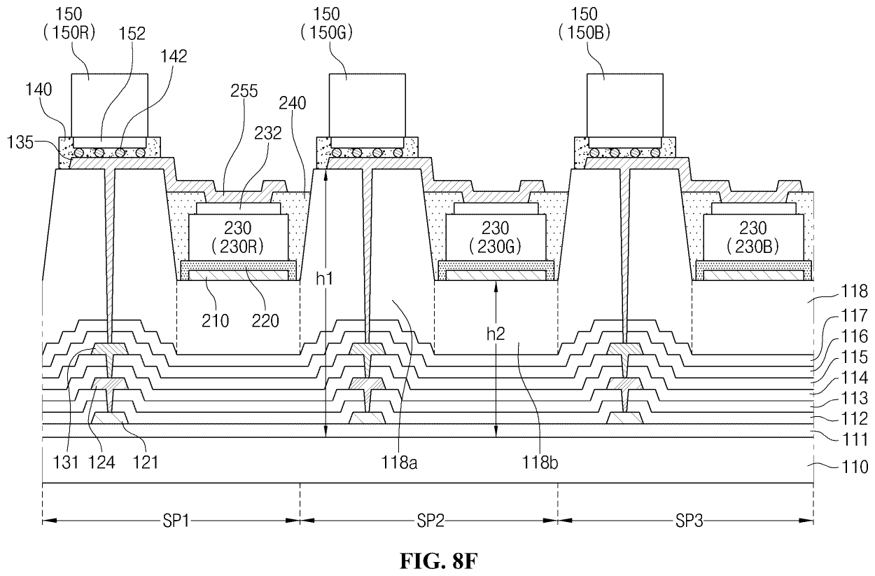

A method of manufacturing a stretchable display device according to the embodiment of the present disclosure will be described with reference to FIGS. 8A to 8F.

FIGS. 8A to 8F are schematic cross-sectional views of a display panel in steps of manufacturing a stretchable display device according to the embodiment of the present disclosure. FIGS. 8A to 8F show cross-sections corresponding to line III-III′ of FIG. 3 and will be described with reference to FIGS. 5 to 7 together.

In FIG. 8A, the first buffer layer 111 may be formed on the base substrate 110; the light shielding layer 121 may be formed on the first buffer layer 111; the second buffer layer 112 may be formed on the light shielding layer 121; the semiconductor layer 122 may be formed on the second buffer layer 112; the gate insulation layer 113 may be formed on the semiconductor layer 122; the gate electrode 123 and the first connection electrode 124 may be formed on the gate insulation layer 113; the first interlayer insulation layer 114 may be formed on the gate electrode 123 and the first connection electrode 124; the auxiliary electrode 125, the auxiliary line 126, and the pad electrode 127 may be formed on the first interlayer insulation layer 114; the first interlayer insulation layer 114 may be formed on the auxiliary electrode 125, the auxiliary line 126, and the pad electrode 127; the source electrode 128, the drain electrode 129, the second connection electrode 131, and the power line 132 may be formed on the second interlayer insulation layer 115; the third interlayer insulation layer 116 may be formed on the source electrode 128, the drain electrode 129, the second connection electrode 131, and the power line 132; the auxiliary pad 133 may be formed on the third interlayer insulation layer 116; and the passivation layer 117 may be formed on the auxiliary pad 133.

Although not shown in the figure, a carrier substrate may be provided under the base substrate 110, the base substrate 110 may be attached on the carrier substrate through a sacrificial layer, and the carrier substrate and the sacrificial layer may be removed later.

Here, the sacrificial layer may be an inorganic layer. For example, the sacrificial layer may be formed by stacking amorphous silicon (a-Si) and silicon nitride (SiNx). In addition, the carrier substrate may be formed of glass.

Then, the planarization layer 118 may be formed on the passivation layer 117 by applying an organic insulating material over substantially the entire surface of the carrier substrate and may be patterned through a photolithography process to thereby form the first portion 118a having the first height h1 and the second portion 118b having the second height h2. In addition, the contact holes exposing the drain electrode 129, the second connection electrode 131, and the auxiliary pad 133 may also be formed. Here, the first height h1 may be greater than the second height h2.

The planarization layer 118 may be formed in the rigid portion A1 and may not be formed in the soft portion A2.

The planarization layer 118 may be formed of an organic insulating material such as photosensitive acrylic polymer (photo acryl), and the organic insulating material may have negative photosensitivity in which a portion exposed to light remains after developing. However, embodiments of the present disclosure are not limited thereto. In other embodiments, the organic insulating material of the planarization layer 118 may have positive photosensitivity in which a portion exposed to light is removed after developing.

The first portion 118a, the second portion 118b, and the contact holes of the planarization layer 118 may be formed using a halftone mask including a light-blocking portion, a light-transmitting portion, and a half light-transmitting portion. When the organic insulating material of the planarization layer 118 has the negative photosensitivity, the first portion 118a may correspond to the light-transmitting portion, the contact holes may correspond to the light-blocking portion, and the second portion 118b may correspond to the half light-transmitting portion.

Alternatively, when the organic insulating material of the planarization layer 118 has the positive photosensitivity, the first portion 118a may correspond to the light-blocking portion, the contact holes may correspond to the light-transmitting portion, and the second portion 118b may correspond to the half light-transmitting portion.

Next, in FIG. 8B, the reflection layer 210 may be formed on the planarization layer 118 by depositing a material having relatively high reflectance and patterning it. The reflection layer 210 may be disposed on the second portion 118b of the planarization layer 118.

In addition, the stretchable line 134 may be formed in the rigid portion A1 and the soft portion A2 by depositing a conductive material on the planarization layer 118 and patterning it through a photolithography process. In the rigid portion A1, the stretchable line 134 may be disposed on the second portion 118b of the planarization layer 118.

The reflection layer 210 and the stretchable line 134 may be formed through the same process. Alternatively, the reflection layer 210 and the stretchable line 134 may be formed through different processes, and the order of formation may not be restricted.

Then, the adhesive layer 220 may be formed on the reflection layer 210 by applying an organic insulating material and first curing it. The adhesive layer 220 may be formed on the second portion 118b of the planarization layer 118 and may not be formed on the first portion 118a. The adhesive layer 220 may cover and the top and side surfaces of the reflection layer 210 and may be in contact with the top surface of the second portion 118b of the planarization layer 118.

Here, the adhesive layer 220 may not be completely cured and may have viscosity. For example, the adhesive layer 220 may be formed of an acryl-based, urethane-based, or silicone-based organic insulating material.

Next, in FIG. 8C, the auxiliary light-emitting element 230 may be transferred on the adhesive layer 220, and the adhesive layer 220 may be secondly cured, thereby fixing the light-emitting element 150 to the adhesive layer 220. In this case, the adhesive layer 220 may be completely cured by applying UV or heat.

The auxiliary light-emitting element 230 may have the bottom surface attached to the adhesive layer 220 and the top surface on which the first auxiliary element electrode 232 and the second auxiliary element electrode 234 are provide. The auxiliary light-emitting element 230 may be disposed over the second portion 118b of the planarization layer 118 and may overlap the reflection layer 210.

Then, an organic insulating material may be applied and cured on the auxiliary light-emitting element 230 and may be selectively removed through a photolithography process, thereby forming the protection layer 240, which has the contact holes exposing the first auxiliary element electrode 232 and the second auxiliary element electrode 234 of the auxiliary light-emitting element 230. The protection layer 240 may be formed over the second portion 118b of the planarization layer 118 and may not be formed over the first portion 118a.

The height of the protection layer 240 from the base substrate 110 may be smaller than the height of the first portion 118a of the planarization layer 118. For example, the difference between the heights of the first portion 118a of the planarization layer 118 and the protection layer 240 may be 1 μm to 2 μm.

Next, in FIG. 8D, the first electrode 135, the second electrode 136, the first contact electrode 255, and the second contact electrode 256 may be formed on the planarization layer 118 and the protection layer 240 by depositing a conductive material and patterning it through a photolithography process.

The first electrode 135 and the second electrode 136 may be disposed on the first portion 118a of the planarization layer 118, and the first contact electrode 255 and the second contact electrode 256 may be disposed on the protection layer 240 provided on the second portion 118b of the planarization layer 118.

The first electrode 135 and the first contact electrode 255 may be connected to each other to be formed as one body, and the second electrode 136 and the second contact electrode 256 may be connected to each other to be formed as one body.

Next, in FIG. 8E, a transfer substrate 300 provided with a transfer film 310 on its bottom surface may be provided over the carrier substrate provided with the first electrode 135, the second electrode 136, the first contact electrode 255, and the second contact electrode 256, pressure may be applied to the top surface of the transfer substrate 300 while heating the carrier substrate, and then the transfer substrate 300 and the transfer film 310 may be detached from the carrier substrate, thereby forming the conductive adhesive layer 140 on the first electrode 135 and the second electrode 136.

The conductive adhesive layer 140 may be formed only on the first portion 118a of the planarization layer 118 and may not be formed on the second portion 118b of the planarization layer 118.

Next, in FIG. 8F, the light-emitting element 150 may be transferred on the conductive adhesive layer 140. Here, the first element electrode 152 and the second element electrode 154 of the light-emitting element 150 may be in contact with the conductive adhesive layer 140.

Then, by applying heat and/or pressure to the light-emitting element 150, the first element electrode 152 and the second element electrode 154 may be electrically connected to the first electrode 135 and the second electrode 136, respectively.

In the above embodiment, it is descried as an example that the light-emitting element 150 is transferred after transferring the auxiliary light-emitting element 230, but embodiments of the present disclosure are not limited thereto. Alternatively, in other embodiments, after transferring the light-emitting element 150, the auxiliary light-emitting element 230 may be transferred. In this case, the connection structure between the first and second electrodes 135 and 135 and the first and second contact electrodes 255 and 256 may vary.

As such, in the method of manufacturing the stretchable display device according to the embodiment of the present disclosure, the conductive adhesive layer 140 can be formed only on the first portion 118a of the planarization layer 118 having the relatively high height due to the step difference, thereby reducing the consumed amount of the anisotropic conductive film for one-time transfer. Then, a conductive adhesive layer can be formed on another display panel using the transfer film 310 remaining on the transfer substrate 300 of FIG. 8E, thereby reducing the manufacturing costs.

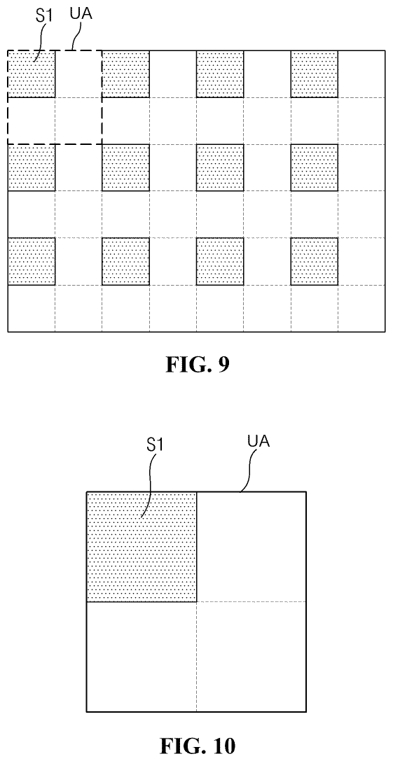

The area and number of transfers of an anisotropic conductive film per unit area according to the embodiment of the present disclosure will be described in detail with reference to FIGS. 9 to 11.

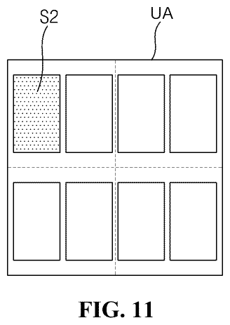

FIG. 9 is a schematic plan view of an anisotropic conductive film according to a comparative example, FIG. 10 is a schematic plan view of a unit area of an anisotropic conductive film according to the comparative example, and FIG. 11 is a schematic plan view of a unit area of an anisotropic conductive film according to the embodiment of the present disclosure.

As shown in FIG. 9 and FIG. 10, in the comparative example, since the anisotropic conductive film is transferred all over the rigid portion, the one-time transfer area S1 may be ¼ of the unit area UA. For example, the area of the unit area UA may be 254 μm×254 μm, and the area of the one-time transfer area S1 may be 127 μm×127 μm. Accordingly, up to four-time transfers are possible with one anisotropic conductive film.

On the other hand, as shown in FIG. 11, in the embodiment of the present disclosure, since the anisotropic conductive film is transferred substantially only to the area corresponding to the light-emitting element 150 of the rigid portion A1, the one-time transfer area S2 may be smaller than ⅛ of the unit area UA. For example, the area of the unit area UA may be 254 μm×254 μm, and the area of the one-time transfer area S2 may be smaller than 56 μm×90 μm. Accordingly, the consumed amount of the anisotropic conductive film for one-time transfer can be reduced, and up to eight-time transfers are possible with one anisotropic conductive film, thereby reducing the manufacturing costs.

In the stretchable display device, by providing the planarization layer having the different heights and forming the conductive adhesive layer only on the portion of the planarization layer having the relatively high height due to the step difference, the consumed amount of the anisotropic conductive film can be reduced, so that the manufacturing costs can be reduced. Even if the light-emitting element is misaligned during the transfer process, the electrical short circuit between the light-emitting element and the signal lines and/or electrodes can be prevented.

In addition, the auxiliary light-emitting element may be further provided on the portion of the planarization layer having the relatively low height, so that the brightness can be improved. When the light-emitting element is defective, the image can be implemented by the auxiliary light-emitting element, so that the lifetime of the display device can be increased.

Accordingly, by improving the lifetime, the production power consumption can be reduced to achieve the low power consumption.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A stretchable display device, comprising:
a base substrate having a rigid portion and a soft portion;
a stretchable line in the soft portion over the base substrate;
a planarization layer in the rigid portion over the base substrate, the planarization layer having a first portion and a second portion of different heights;
a light-emitting element over the first portion of the planarization layer; and
an auxiliary light-emitting element over the second portion of the planarization layer,
wherein a first height of the first portion of the planarization layer from the base substrate is greater than a second height of the second portion of the planarization layer from the base substrate.

2. The stretchable display device of claim 1, wherein the light-emitting element includes a first element electrode and a second element electrode on a bottom surface thereof, and the auxiliary light-emitting element includes a first auxiliary element electrode and a second auxiliary element electrode on a top surface thereof.

3. The stretchable display device of claim 1, further comprising:
a conductive adhesive layer between the light-emitting element and the first portion of the planarization layer,
wherein the conductive adhesive layer is not over the second portion of the planarization layer.

4. The stretchable display device of claim 3, further comprising:
a first electrode and a second electrode between the conductive adhesive layer and the first portion of the planarization layer; and
a first contact electrode and a second contact electrode on the auxiliary light-emitting element,
wherein the first electrode and the first contact electrode are connected to each other and are formed as one body, and the second electrode and the second contact electrode are connected to each other and formed as one body.

5. The stretchable display device of claim 1, wherein the first height of the first portion of the planarization layer from the base substrate is greater than a height of the auxiliary light-emitting element from the base substrate.

6. The stretchable display device of claim 1, further comprising:
a reflection layer between the second portion of the planarization layer and the auxiliary light-emitting element.

7. The stretchable display device of claim 1 wherein the stretchable line extends into and is on the second portion of the planarization layer.

8. A method of manufacturing a stretchable display device, comprising:
preparing a base substrate having a rigid portion and a soft portion;
forming a planarization layer in the rigid portion over the base substrate, the planarization layer having a first portion and a second portion of different heights;
forming a stretchable line in the soft portion over the base substrate;
transferring an auxiliary light-emitting element over the second portion of the planarization layer;
forming a conductive adhesive layer over the first portion of the planarization layer,
transferring a light-emitting element on the conductive adhesive layer,
wherein a first height of the first portion of the planarization layer from the base substrate is greater than a second height of the second portion of the planarization layer from the base substrate.

9. The method of claim 8, wherein the first height of the first portion of the planarization layer from the base substrate is greater than a height of the auxiliary light-emitting element from the base substrate.

10. The method of claim 8, further comprising:
forming a first electrode and a second electrode over the first portion of the planarization layer;
forming a first contact electrode and a second contact electrode over the second portion of the planarization layer between transferring the auxiliary light-emitting element; and
forming the conductive adhesive layer,
wherein the first electrode and the first contact electrode are connected to each other and formed as one body, and the second electrode and the second contact electrode are connected to each other and formed as one body.
